(19) United States
(12) Patent Application Publication
(10) Pub. No.: US 2014/0219307 A1
(43) Pub. Date: Aug. 7, 2014

(54) COMBINED LASER LIGHT SOURCE

(71) Applicant: Hon Hai Precision Industry Co., Ltd., New Taipei (TW)

(72) Inventor: HSIN-SHUN HUANG, New Taipei (TW)

(21) Appl. No.: 13/916,516

(22) Filed: Jun. 12, 2013

(30) Foreign Application Priority Data
Feb. 1, 2013 (TW) 102103876

(51) Int. Cl. H01S 5/026

(52) U.S. Cl. CPC H01S 5/026
USPC 372/50.11

(57) ABSTRACT

A combined laser light source includes a substrate, a waveguide, a first laser source, a second laser source, and a Bragg grating. The substrate includes a top surface, a first side surface, and a second side surface. The waveguide is formed in the top surface and includes a first branch and a second branch connecting with the first branch. The first laser source connects with an entrance of the first entrance and emits a first laser beam into the first branch. The second laser source connects with an entrance of the second entrance and emits a second laser beam into the second branch. The Bragg grating is formed at an interaction of the first branch and the second branch and is configured to reflect the second laser beam into the first branch.

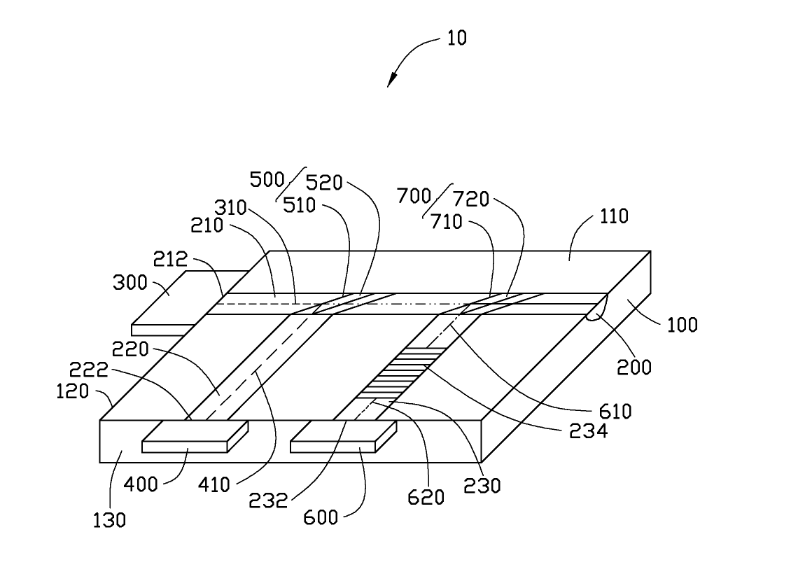

### BACKGROUND

1. Technical Field

The present disclosure relates to lasers and, particularly, to a combined laser light source.

2. Description of Related Art

Combining laser beams often requires complicated optics and therefore current combined laser light sources are typically bulky and costly.

Therefore, it is desirable to provide a combined laser light source, which can overcome the above-mentioned problem.

### BRIEF DESCRIPTION OF THE DRAWING

Many aspects of the present disclosure can be better understood with reference to the following drawing. The components in the drawing are not necessarily drawn to scale, the emphasis instead being placed upon clearly illustrating the principles of the present disclosure.

The FIGURE is an isometric schematic view of a combined laser light source, according to an embodiment.

### DETAILED DESCRIPTION

Embodiments of the present disclosure will be described with reference to the drawing.

The FIGURE is a combined laser light source 10 according to an embodiment. The laser light source 10 includes a substrate 100, a waveguide 200, a first laser source 300, a second laser source 400, and a first Bragg grating 500. The substrate 100 includes a top surface 110, a first side surface 120, and a second side surface 130. The first side surface 120 and the second side surface 130 perpendicularly connect the top surface 110. The waveguide 200 is formed into the top surface 110 by diffusing and includes a first branch 210 and a second branch 220 connecting with the first branch 210. The first branch 210 forms a first entrance 212 in the first side surface 120. The second branch 220 forms a second entrance 222 in the second side surface 130. The first laser source 300 connects with the first entrance 212 and emits a first laser beam 310 into the first branch 210 via the first entrance 212. The second laser source 400 connects with the second entrance 222 and emits a second laser beam 410 into the second branch 220 via the second entrance 222. The first Bragg grating 500 is formed at an interaction of the first branch 210 and the second branch 220 by etching the waveguide 200 and is configured to reflect the second laser beam 410 into the first branch 210. As such, the second laser beam 410 combines with the first laser beam 310.

By employing the substrate 100, the waveguide 200, and the first Bragg grating 500, instead of traditional complicated optics, to combine the first laser beam 310 and the second laser beam 41, size and cost the combined laser light source 10 are reduced, as compared to traditional combined laser light sources.

The substrate 100 is made of lithium niobate. The waveguide 200 is formed by coating a layer of titanium (not shown) corresponding to the waveguide 200 in shape and size and then diffusing the titanium into the substrate 100 by a high temperature diffusing technology. The layer of titanium can be formed by a sputtering and photolithography technology. However, material and formation of the substrate 100 and the waveguide 200 are not limited to this embodiment, but can take into other embodiments other materials and/or forming technologies.

In this embodiment, the first side surface 120 and the second side surface 130 perpendicularly connect with each other, the first branch 210 extends along a direction that is substantially parallel with the second side surface 130, and the second branch 220 runs along a direction that is substantially parallel with the first side surface 120, that is, the second branch 220 is substantially perpendicular to the first branch 210.

The first laser source 300 and the second laser source 400 can be a distributed feedback laser (DFB), which has an emitting side. The first laser source 300 and the second laser source 400 are attached to the first side surface 120 and the second side surface 130 by a die bond technology such that the emitting sides thereof align with the first entrance 212 and the second entrance 222, respectively. The first laser source 300 and the second laser source 400 can also be other-types of laser sources and arranged using suitable technologies. Powers of the first laser source 300 and the second laser source 400 are substantially equal to each other.

In this embodiment, the first laser source 300 is a red laser source and the second laser source 400 is a blue laser source. Accordingly, the first laser beam is red and has a wavelength of about 650 nm while the second laser beam 410 is blue and has a wavelength of about 450 nm. In other embodiments, wavelengths of the first laser source 300 can be changed depending on need.

The first Bragg grating 500 can be formed by a photolithography technology and forms a number of first slits 510 and a number of first media strips 520 alternately arranged, that is, each first media strip 520 is a part of the waveguide 200 left after the parts corresponding to two adjacent first slits 510 are cut out.

According to the following formula:

2*Λ*sinθ=Iλ,

wherein Λ is the grating constant of the first Bragg grating 500, θ is an incident angle of the second laser beam 410 into the first Bragg grating 500, I is a coefficient, and θ is the wavelength of the second laser beam 410.

As such, by appropriately setting the grating constant of the first Bragg grating 500 and the incident angle of the second laser beam 410, the second laser beam 410 can be directed into the first branch 210 by the first Bragg grating 500. In this embodiment, the incident angle of the second laser beam 410 is about 45 degrees.

The waveguide 200 also includes a third branch 230. The third branch 230 perpendicularly connects with the first branch 210 and forms a third entrance 232 in the second side surface 130 or another suitable side surface of the substrate 100. The combined laser light source 10 includes a third laser source 600 connecting with the third entrance 232 and a second Bragg grating 700 formed at an intersection of the first branch 210 and the third branch 230.

The third laser source 600 is also a DFB, which has an emitting side, and is attached to the second side surface 130 by a die bond technology such that the emitting side thereof aligns with the third entrance 232.

In this embodiment, the third laser source 600 is an infrared laser source and emits a third laser beam 620 having a wavelength at about 1050 nm. The third branch 230 is formed with a periodically poled lithium niobate (PPLN) 234. The PPLN 234 can convert the third laser beam 620 into a fourth laser beam 610 utilizing the second-harmonic generation effect. The second Bragg grating 700 reflects the fourth laser beam 610 into the first branch 210. The fourth laser beam 610 combines with the laser beam traversing therein. The fourth laser beam 610 has a wavelength of about 525 nm and a power of the third laser beam 620 is a half of that of the fourth laser beam 610. To ensure combining quality, the power of the fourth laser beam 610 is equal to that of the first laser beam 310 or the second laser beam 410.

The second Bragg grating 700 is structurally similar with the first Bragg grating 500. In detail, the second Bragg includes a number of second slits 710 and a number of second media strips 720 alternately arranged with each other. By appropriately setting the grating constant of the second Bragg grating 700 and the incident angle of the fourth laser beam 610, the fourth laser beam 610 can be directed into the first branch 210 by the second Bragg grating 700. In this embodiment, the incident angle of the fourth laser beam 610 is about 45 degrees.

In other embodiments, the third laser source 600 can be a green laser source having a working wavelength at about 525 nm. The PPLN 234 is omitted. The third laser source 600 emits the fourth laser beam 610 into the third branch 230 via the third entrance 232. The second Bragg grating 700 reflects the fourth laser beam 610 into the first branch 210. The fourth laser beam 610 combines with the laser beam traversing therein.

It will be understood that the above particular embodiments are shown and described by way of illustration only. The principles and the features of the present disclosure may be employed in various and numerous embodiments thereof without departing from the scope of the disclosure. The above-described embodiments illustrate the possible scope of the disclosure but do not restrict the scope of the disclosure.

What is claimed is:

1. A combined laser light source, comprising:
a substrate comprising a top surface, a first side surface, and a second side surface, the first side surface and the second side surface perpendicularly connecting the top surface;
a waveguide formed into the top surface and comprising a first branch and a second branch connecting with the first branch, the first branch forming a first entrance in the first side surface, the second branch forming a second entrance in the second side surface;
a first laser source connecting with the first entrance and configured for emitting a first laser beam into the first branch via the first entrance;
a second laser source connecting with the second entrance and configured for emitting a second laser beam into the second branch via the second entrance; and
a first Bragg grating formed at an interaction of the first branch and the second branch and configured for reflecting the second laser beam into the first branch.

2. The combined laser light source of claim 1, wherein the substrate is made of lithium niobate.

3. The combined laser light source of claim 1, wherein the waveguide is made of lithium niobate diffused with titanium.

4. The combined laser light source of claim 1, wherein the first Bragg grating is formed by defining a plurality of first slits in the waveguide to leave a plurality of a first media strips alternately arranged with the first slits.

5. The combined laser light source of claim 1, wherein the waveguide comprises a third branch, the third branch perpendicularly connects with the first branch and forms a third entrance in the second side surface, the combined laser light source comprises a third laser source connecting with the third entrance and a second Bragg grating formed at an intersection between the first branch and the third branch, the third laser source is configured to emit a third laser beam into the third branch via the third entrance, the second Bragg grating is configured to reflect the third laser beam into the first branch.

6. The combined laser light source of claim 5, wherein the first side surface is substantially perpendicular to the second side surface, both the second branch and the third branch are substantially perpendicular to the second branch, an incident angle of the second beam into the first Bragg grating is about 45 degrees, and an incident angle of the third beam into the second Bragg grating is about 45 degrees.

7. The combined laser light source of claim 5, wherein each of the first laser source, the second laser source, and the third laser source is a distributed feedback laser.

8. The combined laser light source of claim 5, wherein the first laser beam is red, the second laser beam is blue, the third laser beam is green, and powers of the first laser beam, the second laser beam, and the third laser beam are equal to each other.

9. The combined laser light source of claim 5, wherein the second Bragg grating is formed by defining a plurality of second slits in the waveguide to leave a plurality of a second media strips alternately arranged with the second slits.

10. The combined laser light source of claim 1, wherein the waveguide comprises a third branch, the third branch perpendicularly connects with the first branch and forms a third entrance in the second side surface, the combined laser light source comprises a third laser source connecting with the third entrance and a second Bragg grating formed at an intersection between the first branch and the third branch, the third laser source is an infrared laser source and emits a third laser beam, the third branch is formed with a periodically poled lithium niobate which is configured to convert the third laser beam into a fourth laser beam utilizing the second-harmonic generation effect.

11. The combined laser light source of claim 10, wherein the first side surface is substantially perpendicular to the second side surface, both the second branch and the third branch are substantially perpendicular to the second branch, an incident angle of the second beam into the first Bragg grating is about 45 degrees, and an incident angle of the third beam into the second Bragg grating is about 45 degrees.

12. The combined laser light source of claim 10, wherein each of the first laser source, the second laser source, and the third laser source is a distributed feedback laser.

13. The combined laser light source of claim 10, wherein the first laser beam is red, the second laser beam is blue, the fourth laser beam is green, and powers of the first laser beam, the second laser beam, and the fourth laser beam are equal to each other.
